(19) United States
(12) Patent Application Publication
(10) Pub. No.: US 2026/0221381 A1
(43) Pub. Date: Jul. 30, 2026

(54) HIGH-RESOLUTION LOW-DISTORTION IMAGING USING CHARGED-PARTICLE SCANNING MICROSCOPE

(71) Applicant: Carl Zeiss SMT GmbH, Oberkochen (DE)

(72) Inventors: Dmitry KLOCHKOV, Schwaebisch Gmuend (DE); Eugen FOCA, Ellwangen (DE)

(21) Appl. No.: 19/577,920

(22) Filed: Mar. 25, 2026

Related U.S. Application Data
(63) Continuation of application No. PCT/EP2024/076768, filed on Sep. 24, 2024.

(30) Foreign Application Priority Data
Sep. 27, 2023 (DE) 10 2023 126 255.6

(51) Int. Cl. H01J 37/26; G06T 5/50; G06T 5/73; H01J 37/22; H01J 37/28; H01J 37/305

(52) U.S. Cl. CPC H01J 37/263; G06T 5/50; G06T 5/73; H01J 37/222; H01J 37/28; H01J 37/3056; G06T 2207/10061

(57) ABSTRACT

In techniques for obtaining microscopic images having high resolution and low distortion, a transformation is applied to a distorted high-resolution image. The transformation can be determined based on aggregated low-resolution images.

### CROSS-REFERENCE TO RELATED APPLICATIONS

The present application is a continuation of, and claims benefit under 35 USC 120 to, international application No. PCT/EP2024/076768, filed Sep. 24, 2024, which claims benefit under 35 USC 119 of German Application No. 10 2023 126 255.6, filed Sep. 27, 2023. The entire disclosure of each of these applications is incorporated by reference herein.

### FIELD

Various examples generally pertain to imaging using a charged-particle scanning microscope such as a scanning electron microscope. Various examples relate, for example, to digitally postprocessing images acquired using a charged-particle microscope to increase the image quality.

### BACKGROUND

In scanning electron microscopes (SEMs) or other types charged-particle scanning microscopes (e.g., helium ion microscopes), the imaging time is largely defined by the time it takes to scan the field-of-view (FOV) with the electron beam. To increase the signal-to-noise ratio (SNR), one usually increases the so-called dwell time—the time spent by the beam in one pixel. This naturally leads to a larger imaging time.

On the other hand, various instabilities inside the SEM lead to the so-called “drift”—a gradual shift of the FOV relative to the imaging object/sample. Underlying causes for drift include thermal drift, charging, stage instabilities, or beam instabilities. Such a drift can lead to a distortion of the acquired image usually observed as “skewing” or “shear” along X- or Y-direction with an amplitude proportional to the imaging time. This is illustrated in FIG. 1. FIG. 1 illustrates an image 220 acquired using an SEM with a relatively long dwell time, e.g., 1 μs or longer for a 1×1 nm pixel. In FIG. 1 the distortions are clearly visible: depicted are semiconductor structures that include straight lines and circular structures arranged in a square pattern. The straight lines are bent and the square pattern is skewed. Circular structures are skewed end appear elliptical. Techniques are known to mitigate such drift-driven distortions. One approach is so-called fast-frame averaging or drift-corrected frame integration.

In fast-frame averaging, illustrated in FIG. 2, instead of acquiring a single image taken with long dwell time (as in FIG. 1) and having high SNR but also large distortions, a series of fast images 201, 202, 203, 204 with low-SNR and low distortions is acquired at a small dwell time. These fast images 201, 202, 203, 204 are then summed up, at 200. This yields a combined representation 211 of these images 201, 202, 203, 204 (or, simply, a combine image). A challenge of fast-frame averaging is the relative displacement of the FOVs in the fast images due to the aforementioned drift. As a result, aligns the fast images 201, 202, 203, 204 relative to each other before summing them up to produce the final image. This is achieved using a registration. Since the images 201, 202, 203, 204 have low SNR, the computation of their mutual shift typically has limited accuracy which can lead to imperfect alignment. As a result, the combined representation 211 appears “blurred”, i.e., has reduced resolution.

### SUMMARY

It is generally desirable to provide advanced imaging techniques using charged-particle scanning microscopes that mitigate or reduce at least some of the above-identified drawbacks. For example, it is generally desirable to appropriately address a trade-off between resolution loss (blurring) on the one hand and distortion on the other hand. It is generally desirable to obtain distortion free or, at least, low-distortion images having a high resolution.

In an aspect, the disclosure provides a computer-implemented method which comprises controlling a charged-particle scanning microscope to load a sample. The method also includes controlling the charged-particle scanning microscope to acquire one or more first images of the sample using a first imaging setting. The method also includes determining a first localization of multiple features of the sample based on the one or more first images. The method further includes controlling the charged-particle scanning microscope to acquire a second image of the sample using a second imaging setting. The second imaging setting is at least partly different from the first imaging setting. The method further includes determining a second localization of the multiple features based on the second image. The method further includes determining a transformation between the first localization and the second localization. The method further includes transforming the second image based on the transformation.

In an aspect, the disclosure provides a processor configured to load and execute program code. The processor, upon executing the program code, performs a method as disclosed above.

In an aspect, the disclosure provides a program code that can be loaded by a processor and executed by the processor, wherein the processor, upon executing the program code, performs a method as disclosed above.

It is to be understood that the features mentioned above and those explained below may be used not only in the respective combinations indicated, but also in other combinations or in isolation without departing from the scope of the disclosure.

### BRIEF DESCRIPTION OF THE DRAWINGS

FIG. 1 schematically illustrates an SEM image acquired using a comparatively long dwell time according to various examples.

FIG. 2 schematically illustrates multiple SEM images acquired using comparatively short dwell times and a combined representation.

FIG. 3 schematically illustrates a system including a computing device and an SEM according to various examples.

FIG. 4 is a flowchart of a method according to various examples.

FIG. 5 illustrates a first localization of features depicted in a combined representation of multiple first images acquired using an SEM according to various examples.

FIG. 6 illustrates a second localization of features depicted in a second image acquired using an SEM according to various examples.

FIG. 7 schematically illustrates a dual beam device including an SEM and a focused-ion beam device according to various examples.

FIG. 8 schematically illustrates a layer-by-layer milling process according to various examples.

### DETAILED DESCRIPTION

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the disclosure will be described in detail with reference to the accompanying drawings. It is to be understood that the following description of embodiments is not to be taken in a limiting sense. The scope of the disclosure is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Hereinafter, techniques of imaging microscopic samples using charged-particle imaging devices such as SEMs are disclosed.

Techniques are disclosed that enable finding a compromise when imaging with charged-particle scanning microscopes—e.g., SEMs—on samples such as semiconductor wafers: (i) scanning fast with low charge (low particle current/flux or short dwell time per pixel), generally results in poor SNR; while (ii) scanning with high charge (higher particle current/flux or longer dwell time) generally results in good SNR but distortion of the acquired image due to drifts including charging-induced drifts. Techniques are disclosed that enable generating a result image as precise as reasonably possible by combining both methods (i) and (ii).

According to various examples, a superposition of many images acquired at short dwell time and/or small current is determined. This combined representation can have low or zero distortion. This can enable deriving ground-truth information regarding the relative arrangement of depicted features. This ground-truth information can be used to un-distort another image that is acquired using long dwell time and/or high particle current. Specifically, a transformation can be determined based on a comparison of respective localizations of the features in both image types.

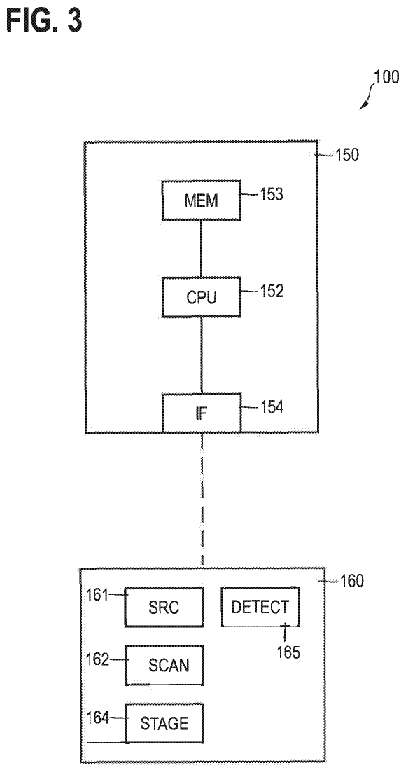

FIG. 3 schematically illustrates a system 100. The system 100 includes a computing device 150 and a charged-particle scanning microscope 160. The computing device 150 includes a processor 152 and a memory 153. The processor 152 can communicate with the charged-particle scanning microscope 160 via a communication interface 154. The processor 152 can load program code from the memory 153 and execute the program code. Upon loading and executing the program code, the processor 152 can perform techniques as disclosed herein, e.g.: controlling the charged-particle scanning microscope to load a sample, acquire images, etc. Also, the processor 152 can manipulate or digitally postprocess images acquired using the charged-particle scanning microscope 160.

For acquisition of images the charged-particle scanning microscope 160 includes a particle source 161, scanning optics 162 configured to divert/scan a primary particle beam emitted by the source 161 and a sample stage/sample holder 164 configured to hold a sample, e.g., a semiconductor or biological sample. Charged particles of a secondary beam are detected by a detector 165. By appropriately controlling the scanning optics 162 to scan the primary particle beam across the sample, multiple measurement points of an image can be acquired. For each measurement point, a certain dwell time is implemented.

Accordingly, a charged-particle scanning microscope such as a SEM produces high-resolution images by scanning a sample with a focused beam of electrons. The source, typically a tungsten filament or field emission gun, emits electrons that are accelerated and focused onto the sample by scanning optics, including electromagnetic lenses. As the electrons interact with the sample, various signals, including secondary electrons, are emitted. These signals are detected by a detector, typically a secondary electron detector, to produce an image. In raster scanning, the electron beam is systematically moved across the sample in a grid-like pattern, pixel by pixel. The time the electron beam spends on each pixel before moving to the next is called the dwell time. Adjusting the dwell time can affect image quality: a longer dwell time can result in a better signal-to-noise ratio, but at the expense of slower scan speeds and increased distortion. Hereinafter, techniques are disclosed that can enable addressing this trade-off by appropriate postprocessing of acquired images.

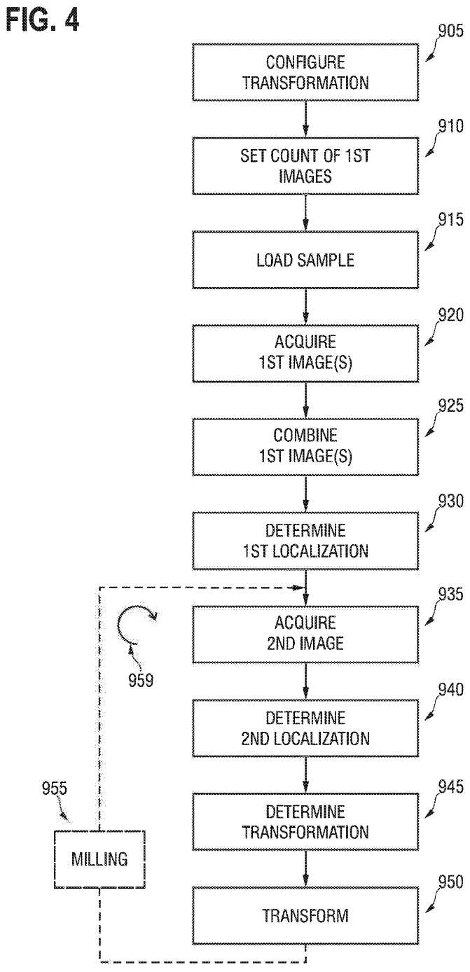

FIG. 4 is a flowchart of a method according to various examples. The method of FIG. 4 can be executed by a computer controlling a charged-particle scanning microscope. The method of FIG. 4 can be executed by the processor 152 of the computing device 150 of the system 100 illustrated in FIG. 3, e.g., upon loading program code from the memory 153 and executing the program code.

The method of FIG. 4 can enable obtaining microscope images of a sample having a relatively low distortion and, at the same time, a relatively high resolution and SNR.

The techniques in FIG. 4 are based on undistorting a second image acquired with a relatively long dwell time (and thus having a relatively large native distortion). This is based on a transformation that quantifies the distortion. The transformation is obtained from one or more first images that are acquired using a small dwell time. Features are localized in the one or more first images and compared with a respective localization of the features in a second image.

At optional box 905, it is possible to configure the transformation. A number of free parameters of the transformation can be determined. The parameters of the transformation can pertain to one or more of: scaling, rotation, shearing, and translation/shifting. For instance, for a linear transformation fewer free parameters are used than for a non-linear transformation of certain order.

The transformation can be configured based on prior knowledge, e.g., an expected magnitude or severity of the distortion. For example, the transformation can be configured based on an imaging setting used to acquire the first image(s) and/or an imaging setting used to acquire the second image and/or a sample type of the sample to-be-imaged and/or a hardware configuration of the microscope. The imaging settings can include a dwell time. The imaging settings can include a scanning pattern. The imaging settings can specify a focal distance. The imaging settings can include a spot size.

Depending on the use case, instrument acquisition mode, and on the lab/fab environment, the exact form of the transformation—specifically, the amount of free parameters—can be chosen accordingly.

Such properties generally have an impact on to the expected severity of the distortion. For a more severe distortion, it is typical to use a larger count of free parameters of the transformation to adequately and accurately capture the distortion. For instance, certain sample types are prone to charging drifts. Certain hardware settings of the charged-particle scanning microscope can be prone to temperature drifts. Based on respective prior knowledge, the count of free parameters of the transformation can be configured appropriately. The count of free parameters can be selected to be as small as reasonably possible but as large as desired.

It is not required in all scenarios to configure the transformation at box 905. In some scenarios, the transformation can be pre-configured, such that box 905 is optional.

At box 910, it is optionally possible to determine a count of the one or more first images serving as a reference (i.e., the one or more images may also be labelled “reference images”). I.e., it is possible to determine how many first images are to be acquired.

The count of the one or more first images can depend on the count of free parameters of the transformation, as determined at box 905. For instance, for a larger count of free parameters, there is typically a tendency to use a larger count of first images, to ensure that each parameter value can be determined at the appropriate accuracy. In detail, a larger count of the first images can result in a higher accuracy of localization of multiple features. This, in turn, can enable determining the transformation more accurately.

For example, if a linear affine transformations is sufficient, only six free parameters are used. This can translate in a relative limited amount of first images, e.g., even a single first image may suffice.

The count of the one or more first images can be chosen as small as reasonably possible, but as large as desired.

Box 910 allows balancing between the quality of the distortion correction (i.e., the amount of residual, uncorrected distortion in the result image) and the imaging time.

Box 910 is optional. In some examples, the count of the one or more first images is predefined.

At optional box 915, the sample to be imaged is loaded. For this, the charged-particle scanning microscope can be controlled to load the sample. A load lock can be opened after flooding a pressure chamber; and once the sample has been placed on a sample holder, the load lock can be closed and the pressure chamber can be evacuated.

The sample can alternatively be pre-loaded.

At box 920, one more first images (also referred to as reference images herein) are acquired. This includes controlling the charged-particle scanning microscope to acquire one or more first images of the sample using a first imaging setting.

These one or more first images can correspond to the SEM images 201-204 shown in FIG. 2.

The stage is not moved in between acquisition of the multiple first images. I.e., the field of view is (at least nominally) fixed. The same measurement site (e.g., stage position) can be used.

If the count of the one or more first images has been previously set at box 910, then this count is used in box 920.

If multiple first images are acquired in box 920, a combined representation of the multiple reference images is determined at box 925. For instance, a pixel wise addition or multiplication or other combination can be executed.

Such a combined representation or combined image 211 has been previously discussed in connection with FIG. 2.

It is possible to perform a registration between the multiple first images. Then, based on the registration, the combination can be executed. In detail, based on the registration, alignment vectors can be determined for each first image and the multiple first images can be aligned by applying the respective alignment vectors.

The combination of the multiple first images can be based on an optimization of an edge sharpness measure. This means that parameters of the combination (e.g., relative weights for each pixel or individual first image) can be adjusted to maximize the sharpness of the edges in the combined representation. The edge sharpness measure can be maximized. The edge sharpness measure can be defined, e.g., as the absolute value of the averaged local gradient at the boundaries of each feature. More generally, the sharpness measure can be included in a merit function which is optimized while computing the alignment vector. This approach can allow reducing the blurriness of the combined representation and, therefore, improving the accuracy of the reference objects localization subsequently executed at box 930.

At box 930, a first localization of multiple features of the sample depicted in the one or more first images is determined based on the one or more first images acquired at box 920. For instance, if box 925 is executed, then the first localization can be determined based on the combined representation of the multiple reference images.

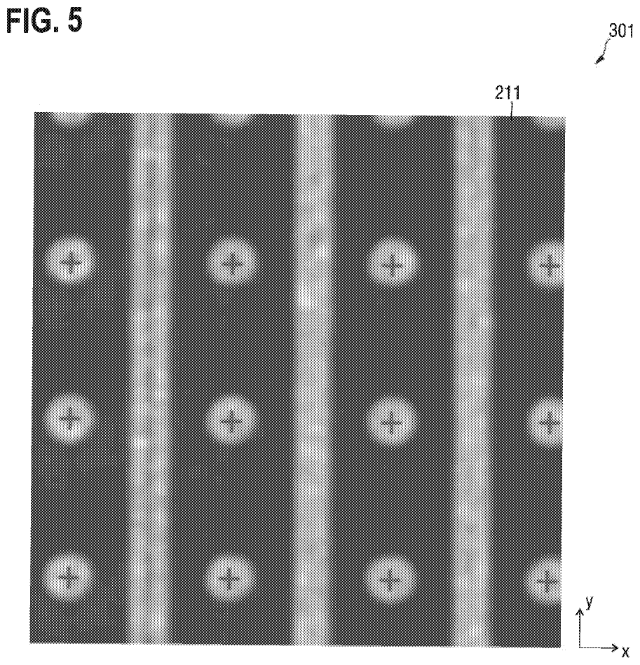

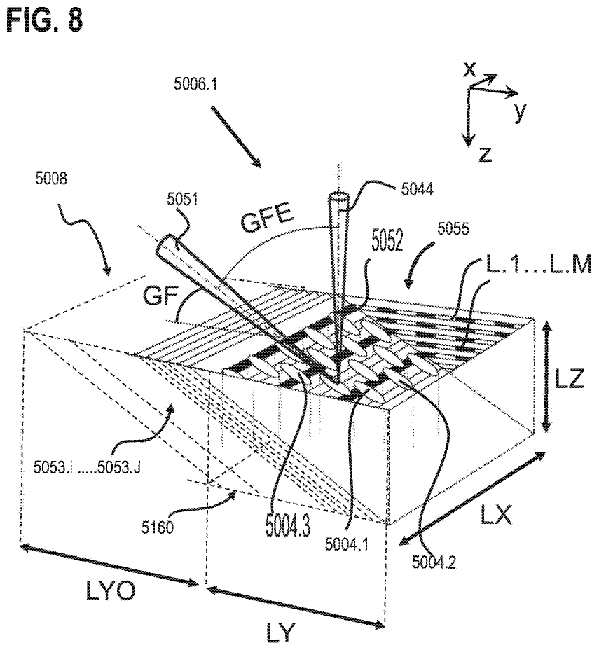

The first localization, accordingly, can serve as ground truth regarding the relative arrangement of the features and, accordingly, can be used to derive a transformation for undistorted a distorted second image. FIG. 5 illustrates an example of such a first localization 301. Here, the center point of multiple circular features—e.g., vertical vias of a three dimensional (3-D) memory structure (such as the one that will discussed in connection with FIG. 8 below)—are located and the collection of these center points (crosses) specifies the reference localization.

Referring again to FIG. 4, box 930 can accordingly include detection of a set of landmark structures and determination of their image coordinates. Since the combined representation of the multiple first images or the single first image is not distorted (or has only little distortion), the coordinates are only subject to stochastic inaccuracies (depending on blurring and SNR), but not systematic inaccuracies. In other words: Since the one or more first images have a comparatively low distortion (they are acquired using a relatively short dwell time), the first localization of the features can be considered as a reference without significant distortion. The first localization, accordingly, can be labeled “reference localization”, as well.

At box 935, a further, second image is acquired. Similar to a box 920, this includes controlling the charged-particle scanning microscope to acquire the second image using a second imaging setting.

The second imaging setting is at least partly different than the first imaging setting used at box 920. Specifically, the dwell time associated with the second imaging setting used at box 935 is larger than the dwell time associated with the first imaging setting used at box 920. Accordingly, the SNR associated with the second imaging setting used at box 935 is larger than the SNR associated with the first imaging setting used at box 920.

The second image is, accordingly, significantly affected by drift-driven distortions, as previously explained.

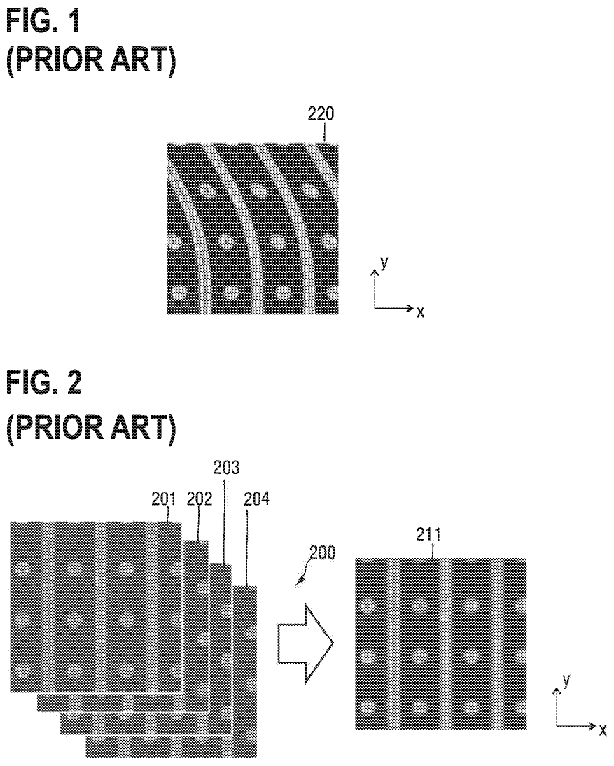

An example of such second image is the image 220 illustrated in FIG. 1.

The second image has a field of view that corresponds to the field of view of the one or more first images acquired at box 920. This means that the same features that are visible in the one or more first images acquired at box 920 are also visible in the second image acquired at box 935. The relative arrangement of those features in the second image is however distorted.

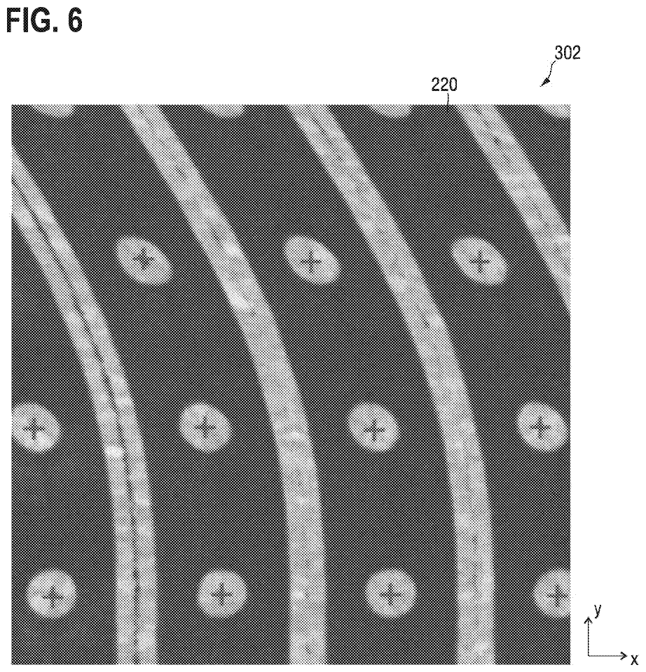

Hence, at box 940, a second localization of the multiple features can be determined based on the further image. This is illustrated in FIG. 6; here, the second localization 302 is illustrated using the cross is localizing the center positions of the circular/elliptic features, for the image 220.

At box 945, the transformation between the first localization determined at box 930 and the second localization determined at box 940 is determined.

Box 945 may include computing mathematical transformations in the form of, e.g., analytical mapping functions

$${x}^{′} = f ( x , y , A , B , … , C )$$

$${y}^{′} = g ( x , y , D , E , … , F )$$

which convert the coordinates (xᵢ, yᵢ) of the features in the second localization determined at box 940 (cf. FIG. 6) to the coordinates (xᵢ′, yᵢ′) of the respective features in the combined representation of the one or more first images or the single first image. The coefficients A, B, . . . C and D, E, . . . F are the parameters of the mapping functions, i.e., the free parameters of the transformation. The functions can be computed using, e.g., least-squared minimization (best-fit) of the deviations in the computed object coordinates vs. measured. As mapping function one can, for example, use linear affine transformation. In some cases, higher-order polynomial transformation functions will be used for an accurate fit. This increases the number of free parameters of the transformation. The number of features localized to fit the transformations should be significantly larger than the number of fit parameters (A, B, . . . C and D, E, . . . F) to avoid overfitting problem. It also helps to mitigate the effect of inaccuracy of the individual feature positions determined at box 930.

At box 950, the further image acquired at box 935 is transformed based on this transformation. This includes applying the transformation or an inverse thereof. This generates a result image having low or zero distortion.

Summarizing, a technique has been disclosed for obtaining a result image having no or low distortion without blurring. To detect a set of features at their “undistorted” locations, a single low-SNR non-distorted reference image or a combined representation of multiple reference images (then typically blurred) can be used. The same features can then be detected in a further image acquired using a large dwell time and thus having high-SNR and significant distortion. Subsequently, an analytical transformation function is computed and applied to the coordinates of the features in the distorted further image to convert them into the coordinates of the respective features in the undistorted one or more reference images. This transformation function can finally be applied to the distorted high-SNR further image to remove or to significantly reduce the distortion. As a result, an “undistorted” high-resolution result image is generated.

Such techniques can be helpful for investigating 3-D memory structures using a slice-and-image tomography technique. Using slice-and-image tomography, a 3-D volume image of semiconductor structures on a nm scale can be obtained. The appearance of these semiconductor structures in the images can be localized as features at box 930 and box 940.

It is possible that between the acquisition of the one or more first images at box 920 of FIG. 4 and the acquisition of the second image at box 935, a layer of material is removed from the sample using a milling process of a slice-and-image tomography technique. This is illustrated by box 955 at which milling occurs. In other words, the first localization determined at box 930 may remain valid for multiple slices of the sample imaged using a respective second image at each iteration of the loop 959. This is because the first localization can be determined based on prior knowledge regarding the relative arrangement and extent of respective semiconductor structures. Such techniques involve the finding that the vertical extent of certain semiconductor structures such as vias in a 3-D memory structure, i.e., having a component extending perpendicular to the milled layer of material, can serve as prior knowledge regarding the appearance of the multiple features. For example, the array structure of such vias in a 3-D memory structure is left unaffected by the milling. Thus, there is no need to re-determine the first localization for subsequent slices imaged by the slice-and-tomography technique. Such techniques can accelerate the overall imaging.

Slice-and-image tomography is often implemented using a dual-beam device. In a dual-beam device, two particle optical systems are arranged at an angle (column offset angle). They co-observe the sample. The two particle optical systems might be oriented perpendicularly or at a column offset angle between 45° and 90°. The first particle optical system defines an imaging column. The imaging column can be implemented by a charged-particle scanning microscope such as a SEM (cf. FIG. 3: microscope 160) or a scanning helium-ion microscope (HIM). The second particle optical system defines a milling column. The milling column can be a focused ion beam (FIB) optical system, using for example Gallium (Ga) ions. The FIB of Ga ions are used to cut off slices of a test volume of the wafer, slice-by-slice. Thereby, images depicting cross-sections of the wafer are obtained at different milling depths, using the imaging column, cf. box 935 for multiple iterations of the loop 959.

An example implementation of the slice-and-image tomographic measurement is described in: Neumann, Jens Timo, et al. “3-D analysis of high-aspect ratio features in 3-D-NAND.” Metrology, Inspection, and Process Control for Microlithography XXXIV. Vol. 11325. International Society for Optics and Photonics, 2020.

Slice-and-image tomographic measurements are also described in WO 2021180600 A1 which is incorporated by reference.

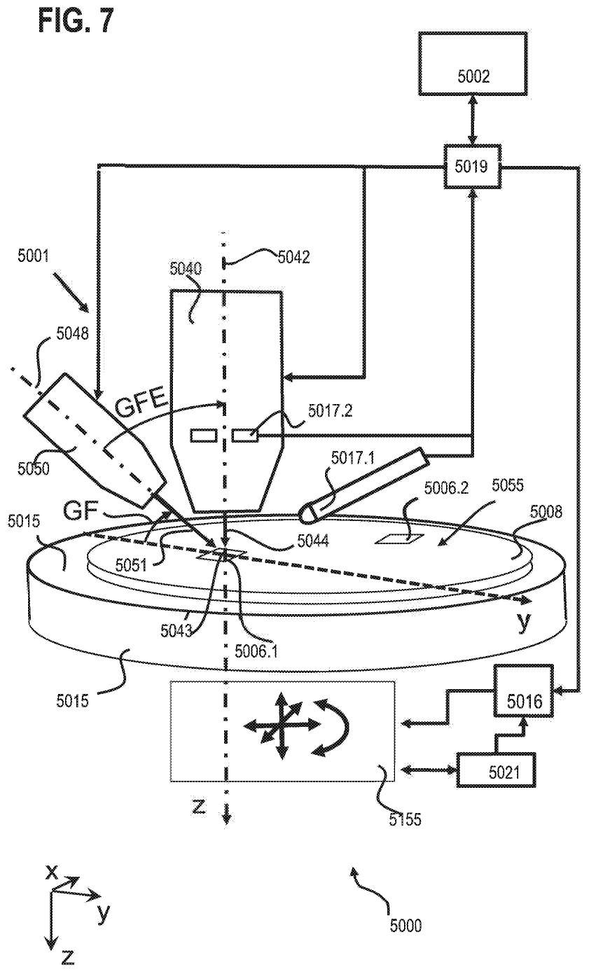

An inspection system is illustrated in FIG. 7. The wafer inspection system 5000 is configured for a slice- and imaging method under wedge cut geometry with a dual beam device 5001. For a wafer 5008, several measurement sites, comprising measurement sites 5006.1 and 5006.2, are defined in a location map or inspection list generated from an inspection tool or from design information. The wafer 5008 is placed on a wafer support table 5015 (corresponding to the sample stage 164). The wafer support table 5015 is mounted on a stage 5155 with actuators and position control 5021. Actuators and mechanisms for precision control 5021 for a wafer stage 5155 such as laser interferometers are known. A control unit 5016 receives information about the actual position of the wafer stage 5155 and is configured to control the wafer stage 5155 and to adjust a measurement site 5006.1 of the wafer 5008 at the intersection point 5043 of the dual-beam device 5001. The dual beam device 5001 is comprising a FIB column 5050 with a FIB optical axis 5048 and a charged particle beam (CPB) imaging system 5040 (e.g., SEM or HIM; cf. FIG. 3: charged-particle scanning microscope 160) with optical axis 5042. At the intersection point 5043 of both optical axes of FIB and CPB imaging system, the wafer surface 5055 is arranged at a slant angle GF to the FIB axis 5048. FIB and CPB co-observe the sample. FIB axis 5048 and CPB imaging system axis 5042 include an angle GFE. In the coordinate system of FIG. 7, the normal to the wafer surface 55 is given by the z-axis. The focused ion beam (FIB) 5051 is generated by the FIB-column 5050 and is impinging under angle GF on the surface 5055 of the wafer 5008. Slanted cross-section surfaces are milled into the wafer by ion beam milling at the inspection site 5006.1 under approximately the slant angle GF at a predetermined y-position, which is controlled by the stage 5155 and position control 5021. In the illustrated example, the slant angle GF is approximately 30°. The actual slant angle of the slanted cross-section surface can deviate from the slant angle GF by up to 1° to 4° due to the beam divergency of the focused ion beam, for example a Gallium-Ion beam, or due to variable material properties with respect to milling along the cross-section surface. With the charged particle beam imaging system 5040, images of the milled surfaces are acquired. Aspects explained above in connection with FIGS. 1-5 apply to such imaging; i.e., a trade-off between low SNR and distortion is to be attained. In the example of FIG. 7, the charged particle beam imaging system 5040 is arranged with its charged particle beam 5044 perpendicular to the wafer surface 5055 and parallel to the z-axis. In other configurations, the optical axis 5042 of the charged particle beam imaging system 40 is arranged at an angle to the z-axis.

During imaging, a beam of charged particles 5044 is scanned by a scanning unit (cf. FIG. 3: scanning optics) of the charged particle beam imaging system 5040 along a scan path over a cross-section surface of the wafer at measurement site 506.1, and secondary particles as well as backscattered particles are generated. Particle detector 5017.1 and optional internal particle detector 5017.2 collect at least some of the secondary particles and/or backscattered particles and communicate the particle count with a control unit 5019. Other detectors (cf. FIG. 3: Detector 165) for other kinds of interaction products such as x-rays or photons may be present as well. Control unit 5019 is in control of the charged particle beam imaging column 5040 and of the FIB column 5050 and connected to a control unit 5016 to control the position of the wafer mounted on the wafer support table 5015 via the wafer stage 5155. Operation control unit 5002 communicates with control unit 5019, which triggers placement and alignment for example of measurement site 5006.1 of the wafer 5008 at the intersection point 5043 via wafer stage movement and triggers repeatedly operations of FIB milling, image acquisition and stage movements. Control unit 5019 and operation control unit 5002 comprises a memory for storing instructions in form of software code and at least one processer to execute during operation the instructions. A memory is further provided to store digital image data. Operation control unit 5002 may further comprise a user interface or an interface to other communication interfaces to receive instructions, prior information and to transfer inspection results.

Each new cross-section surface is milled by the FIB beam 5051 and imaged by the charged particle imaging beam 5044 (cf. FIG. 4: box 935; loop 959).

FIG. 8 illustrate further details of the slice-and-imaging measurement in the wedge cut geometry. By repetition of the slicing and imaging method in wedge-cut geometry, a plurality of J cross-section averaged image slices comprising averaged image slices of cross-section surfaces 5052, 5053.i . . . 5053.J is generated and a 3-D volume image of an inspection volume 5160 at an inspection site 5006.1 of the wafer 5008 is generated. FIG. 8 illustrates the wedge cut geometry at the example of a 3-D-memory stack. The cross-section surfaces 5053.1 . . . 5053.J are milled with a FIB beam 5051 at an angle GF of approximately 30° to the wafer surface 5055, but other angles GF, for example between GF=20° and GF=60° are possible as well. Examples are GF=36° and GF=25°. FIG. 8 illustrates the situation when the surface 5052 is the new cross-section surface which was milled last by FIB 5051. The cross-section surface 5052 is scanned for example by SEM beam 5044 to acquire a respective image slice. The cross-section averaged image slice comprises first cross-section image features, formed by intersections with high aspect ratio (HAR) structures or vias (for example first cross-section image features of HAR-structures 5004.1, 5004.2, and 5004.3) and second cross-section image features formed by intersections with layers L.1 . . . L.M, which comprise for example SiO2, SiN- or Tungsten lines. Some of the lines are also called “word-lines”. The maximum number M of layers is typically more than 50, for example more than 100 or even more than 200. The HAR-structures and layers extend throughout most of the inspection volume in the wafer but may comprise gaps. The HAR structures typically have diameters below 100 nm, for example about 80 nm, or for example 40 nm. The HAR structures are arranged in a regular, for example hexagonal raster with a pitch of about below 300 nm, for example even below 250 nm, or below 60 and below 40 nm (e.g., for DRAM) The appearance of the HAR structures in the SEM images can be used for determining a localization to determine a transformation, as previously explained in connection with FIG. 4: box 930, 940.

Although the disclosure has been shown and described with respect to certain embodiments, equivalents and modifications will occur to others skilled in the art upon the reading and understanding of the specification. The present disclosure includes all such equivalents and modifications and is limited only by the scope of the appended claims.

For illustration, above, various examples have been disclosed in which a dwell time is adjusted between acquisition of images having low SNR and high SNR, respectively. Alternatively or additionally to adjusting the dwell time, it would also be possible to adjust different imaging parameters impacting the SNR, e.g., particle flux/particle current.

What is claimed is:

1. A computer-implemented method, comprising:
controlling a charged-particle scanning microscope to load a sample;
controlling the charged-particle scanning microscope to acquire one or more first images of the sample using a first imaging setting;
determining a first localization of multiple features of the sample based the one or more first images;
controlling the charged-particle scanning microscope to acquire a second image of the sample using a second imaging setting that is at least partly different from the first imaging setting;
determining a second localization of the multiple features based on the second image;
determining a transformation between the first and second localizations; and
transforming the second image based on the transformation.

2. The computer-implemented method of claim 1, wherein:
the one or first more images comprise multiple first images;
the method further comprises determining a combined representation of the multiple first images; and
the first localization is determined based on the combined representation.

3. The computer-implemented method of claim 2, wherein the combined representation is determined based on a pixel-wise combination of the multiple first images.

4. The computer-implemented method of claim 3, wherein the combined representation is determined based on an optimization of an edge sharpness measure.

5. The computer-implemented method of claim 2, wherein the combined representation is determined based on an optimization of an edge sharpness measure.

6. The computer-implemented method of claim 1, wherein the first localization is further determined based on prior knowledge regarding a relative arrangement and/or extent of semiconductor structures associated with the multiple features.

7. The computer-implemented method of claim 1, further comprising:
after acquisition of the one or more first images and prior to acquisition of the second image, controlling a milling process to remove a layer of material from the sample,
wherein semiconductor structures associated with the features have a component extending perpendicular to the layer of material.

8. The computer-implemented method of claim 7, wherein the milling process is a focused-ion beam milling process of a focused ion beam source co-observing the sample with the charged-particle scanning microscope.

9. The computer-implemented method of claim 1, further comprising, based on a count of free parameters of the transformation, determining a count of the one or more first images.

10. The computer-implemented method of claim 9, further comprising determining the count of free parameters of the transformation based on at least one member selected from the group consisting of a hardware configuration of the charged-particle scanning microscope, the first imaging setting, the second imaging setting, and a sample type of the sample.

11. The computer-implemented method of claim 1, wherein a second dwell time associated with the second image setting is greater than a first dwell time associated with the first image setting.

12. The computer-implemented method of claim 1, wherein a particle current associated with the second imaging setting is greater than a particle current associated with the first imaging setting.

13. The computer-implemented method of claim 1, wherein a second signal-to-noise ratio associated with the second imaging setting is greater than a first signal-to-noise ratio associated with the first imaging setting.

14. The computer-implemented method of claim 1, wherein:
the one or first more images comprise multiple first images;
the method further comprises determining a combined representation of the multiple first images;
the first localization is determined based on the combined representation; and
the first localization is further determined based on prior knowledge regarding a relative arrangement and/or extent of semiconductor structures associated with the multiple features.

15. The computer-implemented method of claim 1, wherein:
the one or first more images comprise multiple first images;
the method further comprises determining a combined representation of the multiple first images;
the first localization is determined based on the combined representation;
the method further comprises, after acquisition of the one or more first images and prior to acquisition of the second image, controlling a milling process to remove a layer of material from the sample; and
semiconductor structures associated with the features have a component extending perpendicular to the layer of material.

16. The computer-implemented method of claim 1, wherein:
the one or first more images comprise multiple first images;
the method further comprises determining a combined representation of the multiple first images;
the first localization is determined based on the combined representation; and
the method further comprises, based on a count of free parameters of the transformation, determining a count of the one or more first images.

17. One or more machine-readable hardware storage device comprising instructions that are executable by one or more processing devices to perform operations comprising the method of claim 1.

18. A system, comprising:
one or more processing devices; and
one or more machine-readable hardware storage device comprising instructions that are executable by the one or more processing devices to perform operations comprising the method of claim 1.

19. The system of claim 18, further comprising a charged-particle scanning microscope.

20. The system of claim 19, further comprising a focused ion beam system.
